(19) United States
(12) Patent Application Publication
(10) Pub. No.: US 2014/0077372 A1
(43) Pub. Date: Mar. 20, 2014

(54) SEMICONDUCTOR DEVICE AND METHOD FOR MANUFACTURING THE SAME

(71) Applicant: DONGBU HITEK CO., LTD., Gyeonggi-do (KR)

(72) Inventors: Sung Wook JOO, Gyeongsangnam-do (KR); Chung Kyung Jung, Gyeonggi-do (KR)

(73) Assignee: Dongbu HiTek Co., Ltd., Gyeonggi-do (KR)

(21) Appl. No.: 13/839,316

(22) Filed: Mar. 15, 2013

(30) Foreign Application Priority Data
Sep. 20, 2012 (KR) 10-2012-0104396

(51) Int. Cl. H01L 23/498; H01L 21/48

(52) U.S. Cl. CPC H01L 23/49816; H01L 21/4853
USPC 257/738; 438/613

(57) ABSTRACT

Embodiments relate to a method for manufacturing a semiconductor device including at least one of: (1) Forming a lower electrode pattern on/over a substrate. (2) Forming a first interlayer insulating layer on/over the lower electrode pattern. (3) Forming a second interlayer insulating layer over the first interlayer insulating layer to include an intermediate electrode pattern. (4) Forming an upper electrode pattern over the second interlayer insulating layer. (5) Forming a third interlayer insulating layer over the upper electrode pattern. (6) Etching the first to third interlayer insulating layers to form a cavity which exposes a portion of the intermediate electrode pattern. (7) Forming a contact ball in the cavity.

This application claims the benefit of the Patent Korean Application No. 10-2012-0104396, filed on Sep. 20, 2012, which is hereby incorporated by reference as if fully set forth herein.

### BACKGROUND

Embodiments relate to a semiconductor device and a method for manufacturing a semiconductor device. Some embodiments relate to a Micro Metal Sphere switch and a method for manufacturing a Micro Metal Sphere switch.

A MEMs (Micro Metal Sphere system) device may have a micro-scale size and may perform specific electronic mechanical operation functions. A MEMs device may be produced by (at least in part) by a specialized semiconductor process and/or a low priced batch manufacturing process.

MEMs devices may have many applications, such as sensors, RF switches, micro-resonators, variable capacitors, and/or variable inductors. Examples of sensors include pressure sensors, inertia sensors, position sensors for GPS and game console devices, image sensors in digital cameras and camcorders. Particularly, MEMs devices used in switches may be used for higher assurances of reliability of the switching devices and/or to assure a stable manufacturing yield.

### SUMMARY

Embodiments may relate to a semiconductor device and a method for manufacturing a semiconductor device. Embodiments may relate to a semiconductor device (and/or methods of manufacturing a semiconductor device) which enables improved degrees of freedom of an upper electrode pattern, which may assure reliability of switching action and/or maintain acceptable manufacturing yield.

Embodiments relate to a method of manufacturing a semiconductor device including at least one of the following steps: (1) forming a lower electrode pattern on a substrate, (2) forming a first interlayer insulating layer on the lower electrode pattern, (3) forming a second interlayer insulating layer on the first interlayer insulating layer to include an intermediate electrode pattern, (4) forming an upper electrode pattern on the second interlayer insulating layer, (5) forming a third interlayer insulating layer on the upper electrode pattern, (6) etching the first to third interlayer insulating layers to form a cavity which exposes a portion of the intermediate electrode pattern, and/or (7) forming a contact ball in the cavity.

The intermediate electrode pattern may include a plurality of intermediate electrodes spaced apart from one another, in accordance with embodiments. In embodiments, the step of etching the first to third interlayer insulating layers to form a cavity may include a step of exposing a side of each of the intermediate electrodes. In embodiments, the step of etching the first to third interlayer insulating layers to form a cavity may include a step of exposing a portion of an upper side and/or a portion of an underside of each of the intermediate electrodes adjacent to the side exposed.

The method may include a step of forming an etch stop film between the lower electrode pattern and the first interlayer insulating layer, in accordance with embodiments. In embodiments, the method may include a step of forming a lower contact in contact with the lower electrode pattern that passes through the first interlayer insulating layer and the etch stop film. The intermediate electrode pattern may be formed to be in contact with the lower contact.

The method may include steps of forming a fourth interlayer insulating layer between the second interlayer insulating layer and the upper electrode pattern, and forming an upper contact in contact with the intermediate electrode pattern that passes through the fourth interlayer insulating layer, wherein the upper electrode pattern is formed to be in contact with the upper contact.

In embodiments, the step of etching the first to third interlayer insulating layers to form a cavity may include a step of etching the first to fourth interlayer insulating layers to expose the etch stop film. The step of forming a second interlayer insulating layer on the first interlayer insulating layer to include an intermediate electrode pattern may include steps of forming the second interlayer insulating layer on/over the first interlayer insulating layer, forming a recess in the second interlayer insulating layer, and/or burying a conductive material in the recess to form the intermediate electrode pattern, in accordance with embodiments.

The structure of the upper electrode pattern may include a stack of a lower barrier layer, a main electrode layer, and/or an upper barrier layer, in accordance with embodiments. In embodiments, the main electrode layer may be formed of at least one of Al, Cu, Au, and/or an alloy which includes at least one of Al, Cu, and Au. In embodiments, the intermediate electrode pattern may include at least one of tungsten, Ti, TiN, and/or a TiN/Ti alloy.

In embodiments, a semiconductor device may include at least one of: (1) a substrate, (2) a lower electrode pattern formed on/over the substrate, (3) a first interlayer insulating layer formed on/over the lower electrode pattern, (4) a second interlayer insulating layer formed on/over the first interlayer insulating layer to include an intermediate electrode pattern, (5) an upper electrode pattern formed on/over the second interlayer insulating layer, (6) a third interlayer insulating layer formed on/over the upper electrode pattern, (7) a cavity which may expose a portion of the intermediate electrode pattern that passes through the first to third interlayer insulating layers, and (8) a contact ball formed in the cavity.

In embodiments, the intermediate electrode pattern may include a plurality of intermediate electrodes spaced apart from one another. In embodiments, the cavity may expose a side of each of the intermediate electrodes. In embodiments, the semiconductor device may include at least one of: (1) an etch stop film formed between the lower electrode pattern and the first interlayer insulating layer, (2) a fourth interlayer insulating layer formed between the second interlayer insulating layer and the upper electrode pattern, (3) a lower contact connected between the lower electrode pattern and the intermediate electrode pattern passed through the first interlayer insulating layer and the etch stop film, and (4) an upper contact connected between the upper electrode pattern and the intermediate electrode pattern that passes through the fourth interlayer insulating layer. In embodiments, the cavity may expose the etch stop film that passes through the first to fourth interlayer insulating layers.

### DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 illustrates a section of a semiconductor device, in accordance with embodiments.

FIGS. 2 to 9 illustrate sections showing exemplary steps of a method for manufacturing a semiconductor device, in accordance with embodiments.

FIGS. 10A to 10C illustrate example variations of the intermediate electrode pattern in FIG. 5, in accordance with embodiments.

### DESCRIPTION

FIGS. 2 to 9 illustrate example steps of a method for manufacturing a semiconductor device, in accordance with embodiments. In embodiments, the method for manufacturing a semiconductor device is a method of manufacturing a MEM (Micro Metal Sphere) switch.

As shown in FIG. 2, an insulating layer 120 may be formed on a substrate 110, in accordance with embodiments. The substrate 110 may be at least one of a mono-crystalline silicon substrate, a poly-crystalline silicon substrate, and/or a semiconductor substrate. The substrate 110 may have a device isolation film formed thereon which may divide an active region from a device isolation region. The substrate 110 may have p type impurities or n type impurities doped therein.

The insulating layer 120 may include at least one of oxide or nitride and/or may be single or multi-layered, in accordance with embodiments. In example embodiments, the insulating layer 120 may be deposited on the substrate by CVD (Chemical Vapor Deposition) and may include at least one of (but not limited to) SiO₂, SiₓN_{y} (where, x, and y are real numbers), FSG (Fluoro Silicate glass), USG (Undoped Silicate Glass), BPSG (Boron Phospho Silicate Glass), and TEOS (TetraEthOxySilane).

In embodiments, a lower electrode pattern 130 may be formed on/over the insulating layer 120. The lower electrode pattern 130 may have a stack structure including at least one of a first barrier layer 132, a first main electrode layer 134, and/or a second barrier layer 136. The first barrier layer 132 and the second barrier layer 136 may serve to prevent metal ions of the first main electrode layer 134 from diffusing to other layer (e.g. the insulating layer 120), in accordance with embodiments.

The first and the second barrier layers 132 and 136 may be formed of a barrier material which may block diffusion of the metal ions (e.g. TiN, Ti, a TiN/Ti alloy, and/or similar), in accordance with embodiments. The first main electrode layer 134 may be formed of a material having good conductivity (e.g. Al, Au, Cu, an alloy including at least one of Al, Au, and Cu, an Al—Cu alloy, and/or similar).

The lower electrode pattern 130 may include a plurality of lower electrodes (e.g. 130-1 and 130-2) spaced apart from one another and electrically isolated from one another, in accordance with embodiments. For example, in embodiments, the lower electrode pattern 130 may include a first lower electrode 130-1 and a second lower electrode 130-2 spaced apart from each other and electrically isolated from each other. Although embodiments illustrated in FIG. 2 illustrates only two lower electrodes 130-1 and 130-2, the number of the lower electrodes are not limited to this to two lower electrodes (i.e. there may be three or more lower electrodes), in accordance with embodiments.

For example, in embodiments, by depositing the first barrier layer 132, the first main electrode layer 134, and/or the second barrier layer 136 on/over the insulating layer 120 in succession by CVD (Chemical Vapor Deposition) and patterning the deposited layers 132, 134, and 136 by photolithography and etching, a plurality of lower electrodes (e.g. lower electrodes 130-1 and 130-2) may be formed.

Referring to FIG. 2, in embodiments, the patterning by the photolithography and etching may expose or open sides of the first main electrode layers 134 of the first lower electrode 130-1 and the second lower electrode 130-2 from the first and second barrier layers 132 and 136, respectively. Moreover, the patterning by the photolithography and etching may expose or open a portion of the insulating layer 120, for an example, a portion of an upper side of the insulating layer 120.

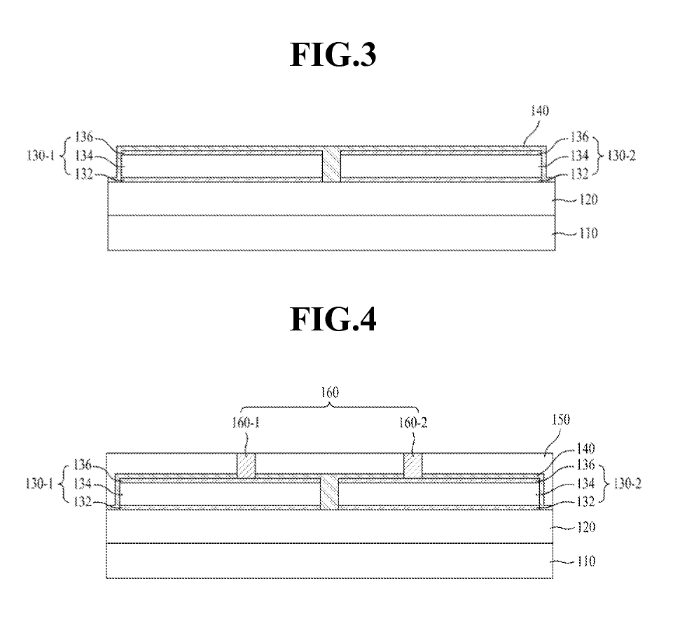

Referring to FIG. 3, in embodiments, an etch stop film 140 may be formed on/over the insulating layer 120 to cover the lower electrode pattern 130. For example, the etch stop film 140 may be formed on exposed sides of the first and second barrier layers 132 and 136, an upper side of the barrier layer 136, and the portion of the insulating layer 120 exposed (e.g. shown by example in FIG. 2), in accordance with embodiments.

The etch stop film 140 may serve as an etch stop film during etching which may provide a space 230-2 shown in FIG. 7 to position a contact ball therein, in accordance with embodiments. The etch stop film 140 may be formed of a material having an etch selectivity higher than an interlayer insulating layer 150 (e.g. silicon nitride SiN).

Referring to FIG. 4, in embodiments, the first interlayer insulating layer 150 may be formed on/over the etch stop film 140. For example, in embodiments, the first interlayer insulating layer 150 may be formed on the etch stop film 140 by CVD (Chemical Vapor Deposition) and may include (but not limited to) at least one of an oxide, a nitride, SiO₂, SiₓN_{y} (where x, and y are real numbers), FSG (Fluoro Silicate glass), USG (Undoped Silicate Glass), BPSG (Boron Phospho Silicate Glass), TEOS (TetraEthOxySilane), and/or similar.

In embodiments, lower contacts 160 may be formed which are in contact with the lower electrode pattern 130 that passes through the first interlayer insulating layer 150 and the etch stop film 140. For example, in embodiments, a first lower contact 160-1 in contact with the first lower electrode 130-1 may pass through a region where both the first interlayer insulating layer 150 and the etch stop film 140 may be formed. A second lower contact 160-2 in contact with the first lower electrode 130-2 may pass through a region where both the first interlayer insulating layer 150 and the etch stop film 140 may be formed, in accordance with embodiments. Although FIG. 4 only illustrates two lower contacts, any practical number of the lower contacts may be possible (e.g. three or more lower contacts). In embodiments, at least one lower contact may be formed to be in contact with one of the plurality of the lower electrodes (e.g. 130-1 and 130-2).

In embodiments, the lower contact 160 may be formed (but not limited to) by at least one of the following steps: (1) A photoresist pattern may be formed on/over the first interlayer insulating layer 150. (2) The first interlayer insulating layer 150 and the etch stop film 140 may be etched by using the photoresist pattern as an etch mask to form a via hole. (3) A conductive material may be filled in the via hole formed and planarized to form the lower contact 160. In embodiments, the conductive material may be tungsten, a barrier metal material, Ti, TiN, a TiN/Ti alloy, and/or similar.

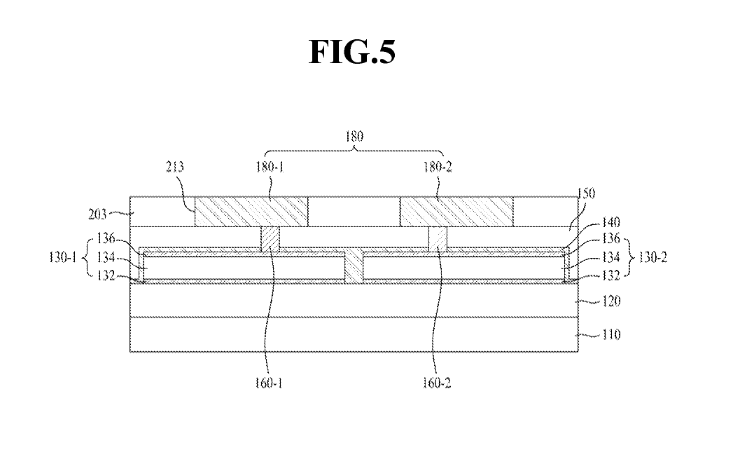

Referring to FIG. 5, in embodiments, a second interlayer insulating layer 203 may have an intermediate electrode pattern 180 formed on/over the first interlayer insulating layer 150. The second interlayer insulating layer 203 may be formed of a material and/or method that is the same, substantially the same, or similar with the first interlayer insulating layer 150. In embodiments, the intermediate electrode pattern 180 may be in contact with the lower contact 160.

For example, in embodiments, the second interlayer insulating layer 203 may be formed on/over the first interlayer insulating layer 150 and a recess 213 may be formed in the second interlayer insulating layer 203 (e.g. by photolithography and etching). In embodiments, a conductive material may be deposited on/over the second interlayer insulating layer 203 to bury the recess 213 with the conductive material and may be planarized until the second interlayer insulating layer 203 is exposed, to form the intermediate electrode pattern 180 buried in the recess 213.

In embodiments, the recess 213 may have a shape based on the shape of the intermediate electrode pattern 180. The conductive material of the intermediate electrode pattern 180 may include a material having a corrosion rate by the etchant of the second etching lower than the second main electrode layer 174 (e.g. tungsten, at least one of the barrier metal material, Ti, TiN, a TiN/Ti alloy, and/or similar). In embodiments, the etchant of the second etching may be a relatively strong acid with a relatively low pH.

The intermediate electrode pattern 180 may include a plurality of intermediate electrodes (e.g. 180-1 and 180-2) spaced apart from one another so as to be electrically separated from one another, in accordance with embodiments. FIG. 5 illustrates two intermediate electrodes (e.g. 180-1 and 180-2), in accordance with embodiments. However, a number of the intermediate electrodes is not limited to two and in embodiments the number of the intermediate electrodes may be three or more.

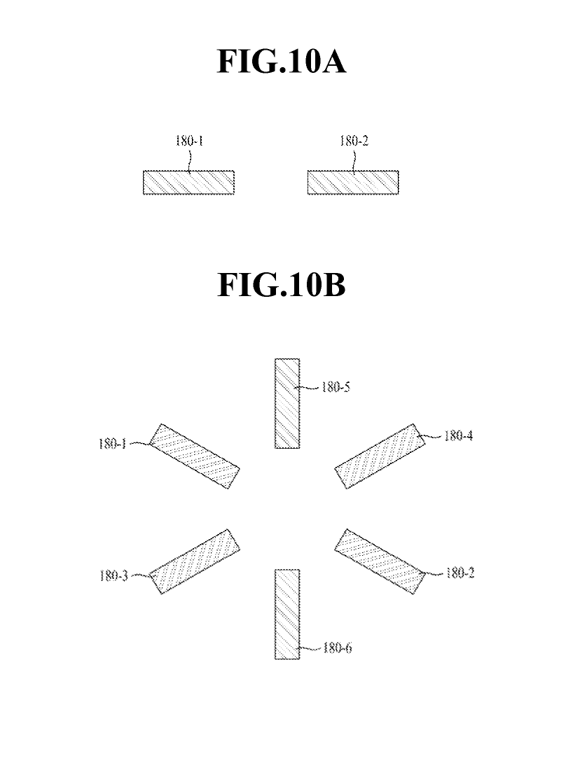

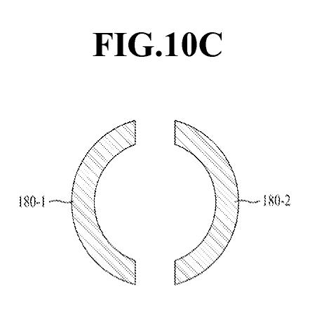

Example FIGS. 10A through 10C illustrate embodiments that are variations of the intermediate electrode pattern 180 illustrated FIG. 5. FIG. 10A illustrates the intermediate electrode pattern 180 having two line shaped intermediate electrodes (e.g. 180-1 and 180-2). FIG. 10B illustrates the intermediate electrode pattern 180 having line shaped intermediate electrodes (e.g 180-1 through 180-5) positioned radially spaced from one another, in accordance with embodiments. FIG. 10C illustrates the intermediate electrode pattern 180 having curved intermediate electrodes (e.g. 180-1′ and 180-2′) arranged symmetrically in a left/right direction to face each other, in accordance with embodiments.

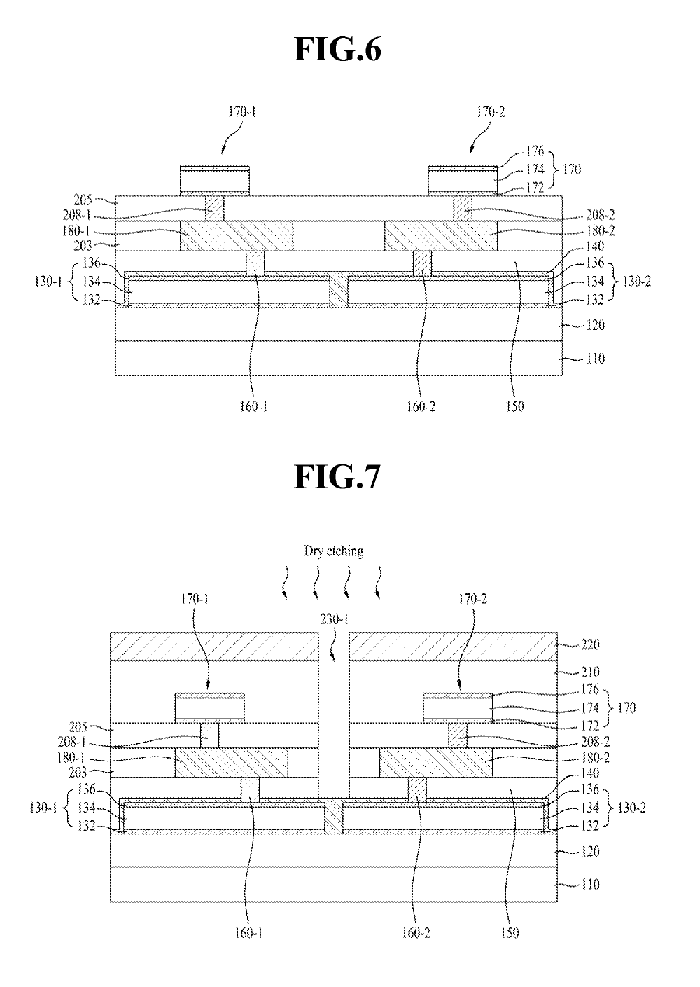

Referring to FIG. 6, a third interlayer insulating layer 205 may be formed on/over the second interlayer insulating layer 203 having the intermediate electrode pattern 180 formed therein. The third interlayer insulating layer 205 may be formed of a material (and in embodiments by a method) that is substantially the same or similar as the first interlayer insulating layer 150, in accordance with embodiments. In embodiments, an upper contact 208 may be formed to be in contact with the intermediate electrode pattern 180 that passes through the third interlayer insulating layer 205.

For example, in embodiments, a first upper contact 208-1 in contact with the first intermediate electrode 180-1 may pass through a region of the third interlayer insulating layer 205 and/or a second upper contact 208-2 in contact with the second intermediate electrode 180-2 that may passe through another region of the third interlayer insulating layer 205.

Although FIG. 6 illustrates only two upper contacts, the number of the upper contacts are not limited to two upper contact (e.g. in embodiments may be three or more). In embodiments, at least one lower contact may be formed to be in contact with one of the plurality of intermediate electrodes (e.g. 180-1 and 180-2). The upper contact 208 may be formed of a material (and in embodiments by a method) that is similar or substantially the same as the lower contact 160, in accordance with embodiments.

In embodiments, an upper electrode pattern 170 may be formed on/over the third interlayer insulating layer 205. The upper electrode pattern 170 may have a stack structure including at least one of a third barrier layer 172, a second main electrode layer 174, and a fourth barrier layer 176, in accordance with embodiments. The third barrier layer 172 and/or the fourth barrier layer 176 may serve to substantially prevent metal ions of the second main electrode layer 174 from diffusing to other layers (e.g. the first and second interlayer insulating layers 150 and 210).

The third and fourth barrier layers 172 and 176 may be formed of a barrier metal material (e.g. TiN, Ti, a TiN/Ti alloy, or similar). The second main electrode layer 174 may be formed of a material having relatively good conductivity (e.g. Al, Cu, Au, an alloy including at least one of Al, Cu, and Au, an alloy including at least any one of Al, Au, and Cu, an Al—Cu alloy, and/or similar).

The upper electrode pattern 170 may include a plurality of upper electrodes (e.g. 170-1 and 170-2) spaced apart from one another to be electrically isolated from one another. For example, in embodiments, the upper electrode pattern 170 may include the first upper electrode 170-1 and the second upper electrode 170-2.

For example, in embodiments, by depositing the third barrier layer 172, the second main electrode layer 174, and/or the fourth barrier layer 176 on/over the first interlayer insulating layer 150 by CVD (Chemical Vapor Deposition) in succession, patterning the deposited layers 172, 174, and 176 by photolithography and etching, the plurality of the upper electrodes (e.g. 170-1 and 170-2) may be formed to be spaced from one another.

The upper electrode pattern 170 may be electrically connected to the intermediate electrode pattern 180 with the upper contact 208, in accordance with embodiments. For an example, in embodiments, the first upper electrode 170-1 may be electrically connected to the first intermediate electrode 180-1 with the first upper contact 208-1. The second upper electrode 170-2 may be electrically connected to the second intermediate electrode 180-2 with the second upper contact 208-2.

At least one of the plurality of the upper electrodes may be positioned on/over the upper contact 208 and may be in contact to the upper contact 208. For example, in embodiments, a portion of the first upper electrode 170-1 may be positioned on/over the first upper contact 208-1 and may be in contact with the first upper contact 208-1. A portion of the second upper electrode 170-2 may be positioned on/over the second upper contact 208-2 and may be in contact with the second upper contact 208-2, in accordance with embodiments.

Referring to FIG. 7, a fourth interlayer insulating layer 210 may be formed on/over the third interlayer insulating layer 205 to cover the upper electrode pattern 170, in accordance with embodiments. In embodiments, the fourth interlayer insulating layer 210 may be formed of a material and by a method that is the same or substantially similar with the first interlayer insulating layer 150.

In embodiments, a photoresist pattern 220 may be formed on/over the fourth interlayer insulating layer 210 by photolithography. In embodiments, the photoresist pattern 220 may expose at least a portion of an upper side of the fourth interlayer insulating layer 210 positioned between the plurality of the upper electrodes (e.g. 170-1 and 170-2).

In embodiments, a first etching is performed, in which fourth interlayer insulating layer 210, the third interlayer insulating layer 205, the second interlayer insulating layer 203, and/or the first interlayer insulating layer 150 may be etched by using the photoresist pattern 220 as an etch mask to form a hole 230-1 which may expose the etch stop film 140. In embodiments, the first etching may be dry etching or similar. The etch stop film 140 may serve as an etch stop film in the first etching and the hole 230-1 may expose a portion of the etch stop film 140, but not the upper electrode pattern 170, in accordance with embodiments.

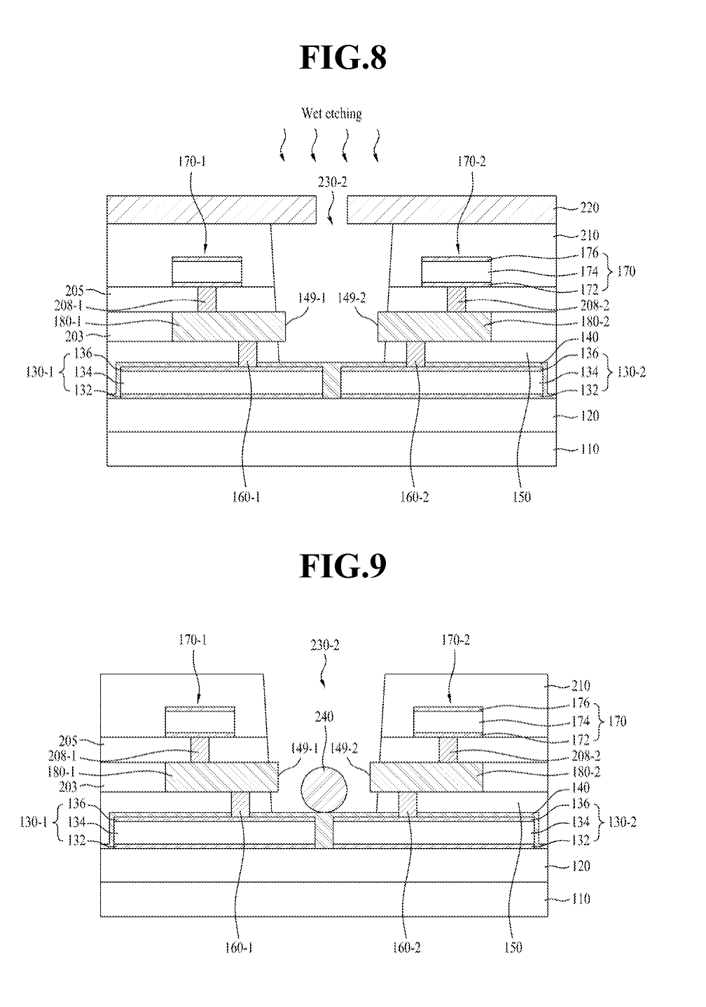

Referring to FIG. 8, a second etching may be performed, in which the first to fourth interlayer insulating layers 150, 203, 205, and 210 etched in the first etching are etched by using the photoresist pattern 220 as an etch mask to form a cavity 230-2 which may expose the intermediate electrode pattern 180, in accordance with embodiments. In embodiments, the cavity 230-2 may be formed to have a top side with a diameter R1 smaller than a diameter R2 of a center portion of the cavity 230-2.

Only a side 149-1 or 149-2 of each of the intermediate electrodes (e.g. 180-1, and 180-2) facing and adjacent to the cavity 230-2 may have a contact ball positioned therein may be exposed, in accordance with embodiments. In embodiments, a portion of an upper side and a portion of an underside of the intermediate electrode (e.g. 180-1 or 180-2) adjacent to the side 149-1 or 149-2 exposed thus may be exposed.

In example embodiments, the second etching may be a wet etching using an etchant which is a mixture of DIW (DeIonized Water) mixed with an HF group chemical. In the second etching, the etchant may flow into the hole 230-1 to etch the first to fourth interlayer insulating layers 150, 203, 204, and 210, in accordance with embodiments.

The second etching may not expose the side of the upper electrode pattern 170, in accordance with embodiments. Since a distance from the cavity 230-2 to the upper electrode pattern 170 may be larger than a distance from the cavity 230-2 to the intermediate electrode pattern 180, the second etching may not expose the upper electrode pattern 170 even if the intermediate electrode pattern 180 is exposed. For example, in embodiments, the cavity 230-2 after the second etching may have a diameter which becomes the smaller as the cavity 230-2 goes from a top side (e.g. near the opening) to a bottom side.

In embodiments, the second etching may include at least one of the following two steps: The first step may include etching for 1 to 20 minutes with DHF (Diluted HF) with an HF to H₂O ratio of 1˜1000:1, and/or the second step may include etching for 1 to 20 minutes with BHF (Buffered HF) with an NH₄F to HF ratio of 3˜100:1.

Referring to FIG. 9, in accordance with embodiments, a remaining photoresist pattern 220 may be removed and a contact ball 240 may be formed on the etch stop film 140 in the cavity 230-2. For example, in embodiments, the contact ball 240 may be formed by at least one of the following steps: (1) A conductive material layer (e.g. a metal layer) may be formed on/over the etch stop film 140 in the photoresist pattern 220 and/or the cavity 230-2 for forming the contact ball 240. (2) A lift-off may be performed to remove the photoresist pattern 220 and the conductive material layer positioned thereon, altogether. The lift-off may not remove the conductive material layer positioned on/over the etch stop film 140 in the cavity 230-2 to leave a portion of the conductive material on the etch stop film 140 in the cavity 230-2. (3) The portion of the conductive material that remains in the cavity 230-2 may be subjected to annealing to form the contact ball 240 on/over the etch stop film 140 in the cavity 230-2. The cavity 230-2 may form an air void and as the contact ball 240 is brought into contact with any one of the exposed side 149-1 of the first intermediate electrode 180-1 and the exposed side 149-2 of the second intermediate electrode 180-2, the semiconductor device may be able to perform the switching action.

If the sides of the first upper electrode 170-1 and the second upper electrode 170-2 are etched in the second etching for contact with the contact ball 240 while omitting formation of the intermediate electrode pattern 180, the second etching may cause damage or loss of the first upper electrode 170-1 and the second upper electrode 170-2, causing malfunction of the switching of the semiconductor device, thereby dropping reliability and a yield of the semiconductor device. This may be due to the material of the second main electrode layer 174 of each of the first upper electrode 170-1 and the second upper electrode 170-2 (e.g. Cu, Al, Au, a Cu—Al alloy, or similar) may be susceptible to loss or damage by the etchant in the second etching.

However, embodiments may prevent the upper electrode pattern 170 from being lost or damaged by the second etching, by forming the intermediate electrode pattern 180 respectively electrically connected to the lower electrode pattern and the upper electrode pattern 170 with the lower contact 160 and the upper contact 208, and exposing not the upper electrode pattern 170, but the intermediate electrode pattern 180 having a corrosion rate lower than the upper electrode pattern 170 in the second etching. Eventually, the formation of the upper electrode pattern 170 of a material insensitive to the wet etching etchant for securing the cavity 230-2 the contact ball is positioned therein enables may improve degrees of freedom of the upper electrode pattern 170, which may assure reliability of switching action of the semiconductor device and may prevent the manufacturing yield from deteriorating, in accordance with embodiments.

Embodiments may reduce the number of steps of photolithography and/or etching as a spacer forming step and a sealing step required for protecting a side wall of the upper electrode pattern 170 from the second etching.

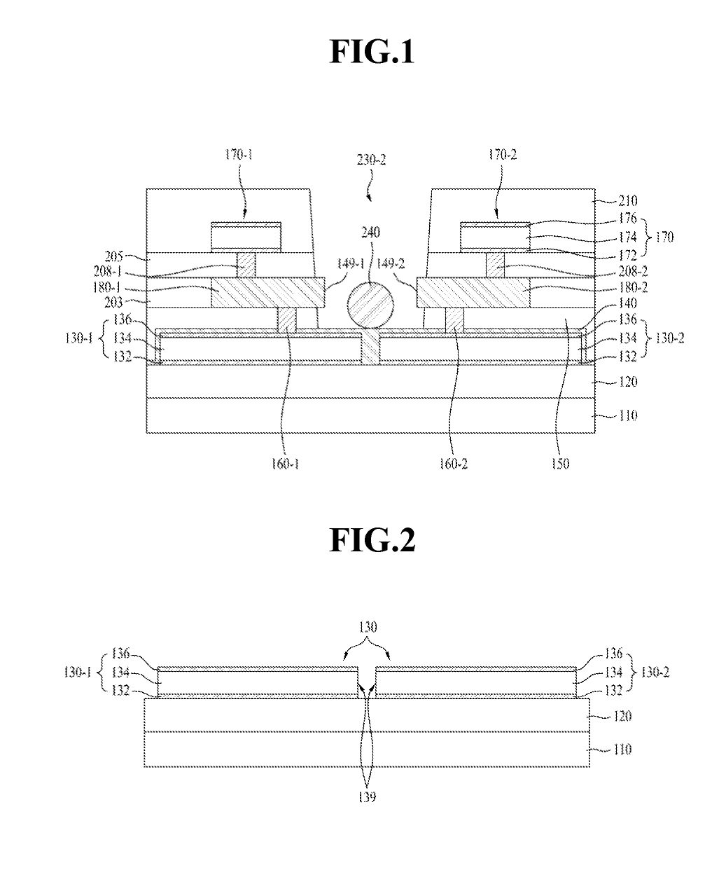

Example FIG. 1 illustrates a section of a semiconductor device 100 in accordance with embodiments. The semiconductor device 100 may be a Micro Metal Sphere switch. The semiconductor device 100 includes at least one of: (1) an insulating layer 120 formed on/over a substrate 110, (2) a lower electrode pattern 130 formed on/over the insulating layer 120, (3) an etch stop film 140 formed on/over the lower electrode pattern 130 and/or the insulating layer 120, (4) a first interlayer insulating layer 150 formed on/over the etch stop film 140, (5) a lower contact 160 connected to the lower electrode pattern 130 passing through the first interlayer insulating layer 150, (6) a second interlayer insulating layer 203 formed on/over the first interlayer insulating layer 150 to include an intermediate electrode pattern 180 connected to the lower contact 160, (7) a third interlayer insulating layer 205 formed on/over the second interlayer insulating layer 203, (8) an upper electrode pattern 170 formed on/over the third interlayer insulating layer 205, (9) an upper contact 208-1 and 208-2 connected between the intermediate electrode pattern 180 and the upper electrode pattern 170 passing through the third interlayer insulating layer 205, (10) a fourth interlayer insulating layer 210 formed on/over the upper electrode pattern 170, (11) a cavity 230-2 formed in the first to fourth interlayer insulating layers 150, 203, 205, and 210 which may expose a portion of the intermediate electrode pattern 180, and/or (12) a contact ball 240 formed in the cavity.

The intermediate electrode pattern 180 may include a plurality of intermediate electrodes (e.g. 180-1 and 180-2) spaced apart from one another, in accordance with embodiments. In embodiments, the cavity 230-2 may expose sides 149-1 and 149-2 of each of the intermediate electrodes (e.g. 180-1 and 180-2). The lower contacts 160-1 and 160-2 may electrically connect the intermediate electrodes 180-1 and 180-2 to the lower electrodes 130-1 and 130-2 respectively, in accordance with embodiments. The upper contacts 208-1 and 208-2 may electrically connect the intermediate electrodes 180-1 and 180-2 to the upper electrodes 170-1 and 170-2, in accordance with embodiments.

The cavity 230-1 may expose a portion of an upper side and a portion of an underside of each of the intermediate electrodes (e.g. 180-1 and 180-2) adjacent to the exposed sides 149-1 and 149-2 of the intermediate electrodes (e.g. 180-1 and 180-2), in accordance with embodiments. In embodiments, the cavity 230-1 may expose the etch stop film 140.

In embodiments, the contact ball 240 may be brought into contact with the side 149-1 of the first intermediate electrode 180-1 and/or the side 149-2 of the second intermediate electrode 180-2, which may be exposed by the cavity 230-2. A switching action of the semiconductor device may be determined based on which one of the side 149-1 of the first intermediate electrode 180-1 and the side 149-2 of the second intermediate electrode 180-2 the contact ball 240 is brought into contact, in accordance with embodiments.

For example, in embodiments, the upper electrode pattern 170 may further include a third upper electrode electrically separated from the first upper electrode 170-1 and the second upper electrode 170-2. The intermediate electrode pattern 180 may further include a third intermediate electrode electrically separated from the first intermediate electrode 180-1 and the second intermediate electrode 180-2, in accordance with embodiments.

In embodiments, if the contact ball 240 is brought into contact with the first intermediate electrode 180-1 and the third intermediate electrode at the same time, a first switching operating may take place, in which the first upper electrode 170-1 and the third upper electrode are electrically connected. If the contact ball 240 is brought into contact with the second intermediate electrode 180-2 and the third intermediate electrode at the same time, a second switching operating may take place, in which the second upper electrode 170-2 and the third upper electrode are electrically connected, in accordance with embodiments.

Embodiments may permits improve degrees of freedom of the upper electrode pattern, which may assure reliability of switching actions of the semiconductor device and/or prevent a manufacturing yield from deteriorating.

Characteristics, structures, effects, and so on described in above embodiments are included to at least one of the embodiments, but not limited to only one embodiment invariably. Furthermore, it is apparent that the features, the structures, the effects, and so on described in the embodiments can be combined, or modified with other embodiments by persons skilled in this field of art. Therefore, it is required to understand that such combination and modification is included to scope of the embodiments.

What is claimed is:

1. A method comprising:
forming a lower electrode pattern over a substrate;
forming a first interlayer insulating layer over the lower electrode pattern;
forming a second interlayer insulating layer over the first interlayer insulating layer to form an intermediate electrode pattern;
forming an upper electrode pattern over the second interlayer insulating layer;
forming a third interlayer insulating layer over the upper electrode pattern;
etching the first interlayer insulating layer, the second interlayer insulating layer, and the third interlayer insulating layer to form a cavity which exposes a portion of the intermediate electrode pattern; and
forming a contact ball in the cavity.

2. The method of claim 1, wherein the intermediate electrode pattern includes a plurality of intermediate electrodes spaced apart from one another.

3. The method of claim 2, wherein said etching comprises exposing a side of each of the intermediate electrodes.

4. The method of claim 3, wherein said etching comprises exposing a portion of an upper side and a portion of an underside of each of the intermediate electrodes adjacent to the exposed side.

5. The method of claim 1, comprising forming an etch stop film between the lower electrode pattern and the first interlayer insulating layer.

6. The method of claim 5, comprising forming a lower contact in contact with the lower electrode pattern that passes through the first interlayer insulating layer and the etch stop film, wherein the intermediate electrode pattern is formed to be in contact with the lower contact.

7. The method of claim 6, comprising:
forming a fourth interlayer insulating layer between the second interlayer insulating layer and the upper electrode pattern; and
forming an upper contact in contact with the intermediate electrode pattern that passes through the fourth interlayer insulating layer, wherein the upper electrode pattern is formed to be in contact with the upper contact.

8. The method of claim 7, wherein said etching the first interlayer insulating layer, the second interlayer insulating layer, and the third interlayer insulating layer to form a cavity comprises etching the fourth interlayer insulating layer to expose the etch stop film.

9. The method of claim 1, wherein the forming a second interlayer insulating layer over the first interlayer insulating layer to include an intermediate electrode pattern comprises:
forming the second interlayer insulating layer over the first interlayer insulating layer;
forming a recess in the second interlayer insulating layer; and
burying a conductive material in the recess to form the intermediate electrode pattern.

10. The method of claim 1, wherein:
the upper electrode pattern has a stack structure comprising a lower barrier layer, a main electrode layer, and an upper barrier layer;
the main electrode layer is formed of at least one of Al, Cu, Au, and an alloy which includes at least one of Al, Cu, and Au; and
the intermediate electrode pattern comprises at least one of tungsten, Ti, TiN, and a TiN/Ti alloy.

11. A semiconductor device comprising:
a substrate;
a lower electrode pattern formed over the substrate;
a first interlayer insulating layer formed over the lower electrode pattern;
a second interlayer insulating layer formed over the first interlayer insulating layer to form an intermediate electrode pattern;
an upper electrode pattern formed over the second interlayer insulating layer;
a third interlayer insulating layer formed over the upper electrode pattern;
a cavity which exposes a portion of the intermediate electrode pattern that passes through the first interlayer insulating layer, the second interlayer insulating layer, and the third interlayer insulating layer; and
a contact ball formed in the cavity.

12. The semiconductor device of claim 11, wherein:
the intermediate electrode pattern comprises a plurality of intermediate electrodes spaced apart from one another; and
the cavity exposes a side of each of the intermediate electrodes.

13. The semiconductor device of claim 11, comprising:
an etch stop film formed between the lower electrode pattern and the first interlayer insulating layer;
a fourth interlayer insulating layer formed between the second interlayer insulating layer and the upper electrode pattern;
a lower contact connected between the lower electrode pattern and the intermediate electrode pattern passing through the first interlayer insulating layer and the etch stop film; and
an upper contact connected between the upper electrode pattern and the intermediate electrode pattern passing through the fourth interlayer insulating layer.

14. The semiconductor device of claim 13, wherein the cavity exposes the etch stop film passing through the first interlayer insulating layer, the second interlayer insulating layer, the third interlayer insulating layer, and the fourth interlayer insulating layer.
